(19) United States
(12) Patent Application Publication
(10) Pub. No.: US 2005/0088059 A1
(43) Pub. Date: Apr. 28, 2005

(54) Power generation device and power generation method

(75) Inventors: Norio Ohkubo, Tokyo (JP); Masayuki Miyazaki, Tokyo (JP); Hidetoshi Tanaka, Kokubunji (JP); Goichi Ono, Saitama (JP)

Correspondence Address: Stanley P. Fisher;Reed Smith LLP, Suite 1400, 3110 Fairview Park Drive, Falls Church, VA, 22042-4503, US

(73) Assignee: Hitachi., Ltd.

(21) Appl. No.: 10/878,549

(22) Filed: Jun. 29, 2004

(30) Foreign Application Priority Data
Oct. 24, 2003 (JP) 2003-364043

(51) Int. Cl. H01L 41/107

(52) U.S. Cl. 310/319

(57) ABSTRACT

There is provided a generator generating power from vibration, capable of increasing a power generation voltage even if the vibration is small in amplitude to thereby enhance efficiency of power generation. A vibration power generator, provided with a mechanism for converting vibrational energy into electrical energy, comprises a switch for switching over whether or not power is outputted, and control of the switch is executed by periodic control thereof such that switchover occurs between respective time periods for outputting the power and respective time periods for not outputting the power at cycles not less than twice and not more than 100 times cycles of vibration. With the invention, efficiency of the generator can be enhanced, and it is possible to provide electronic equipment without power supply from outside, and capable of saving trouble of battery replacement.

### CLAIM OF PRIORITY

The present application claims priority from Japanese patent application JP 2003-364043 filed on Oct. 24, 2003, the content of which is hereby incorporated by reference into this application.

### FIELD OF THE INVENTION

The invention relates to a generator provided with a mechanism for converting vibrational energy into electrical energy, and more particularly, to a generator effective in application for operating, for example, an electronic device installed at a location where vibration occurs, requiring no battery.

### BACKGROUND OF THE INVENTION

As to a generator provided with a mechanism for converting vibrational energy into electrical energy, there has thus far been disclosed a generator using piezoelectric elements (refer to, for example, Patent document 1). Also, there has thus far been disclosed a method of generating electricity from variation in electrostatic capacity (refer to, for example, non-patent document 1).
Patent document 1: JP-A No. 49388/1995
Non-patent document 1: IEEE Transaction on VLSI Systems, Vol. 9, No. 1, 2001, pp. 64-76

In a conventional generator for converting vibrational energy into electrical energy, the vibrational energy has been converted into the electrical energy for every cycle of vibration. This method has had a problem in that power generation voltage was not sufficiently obtained because sufficient consideration was not given to the case where vibration was small in amplitude.

Although there are available means for boosting voltage when the voltage is low, such means are undesirable because of a problem of a loss occurring upon conversion of the voltage. Also, there exists another problem that a loss in a rectifying circuit increases when the power generation voltage is low. This is because a constant voltage is required in the rectifying circuit, and the lower the power generation voltage, the poorer rectification efficiency turns.

### SUMMARY OF THE INVENTION

It is therefore an object of the present invention to provide a generator generating electricity from vibration, capable of increasing a power generation voltage even if the vibration is small in amplitude.

Outlines of representative embodiments of the invention developed to that end, disclosed in the present application, are briefly described as follows.

That is, a power generation device according to the invention is a generator for converting vibrational energy into electrical energy, comprising a switch for switching over whether or not power is outputted, and control of the switch is executed by periodic control thereof such that switchover occurs between respective time periods for outputting the power and respective time periods for not outputting the power at cycles not less than twice and not more than 100 times cycles of vibration.

Further, the power generation device according to the invention may be a generator for converting vibrational energy into electrical energy, comprising a switch for switching over whether or not power is outputted, and a circuit for measuring a period of vibration, wherein control of the switch is the periodic control executed such that respective time periods for outputting the power are equivalent to a time period M-times the period of the vibration while respective time periods for not outputting the power are equivalent to a time period N-times the period of the vibration.

More specifically, the invention provides a power generation device comprising a vibration power generation unit, a control circuit for controlling the vibration power generation unit, a counter for feeding the control circuit with a clock on the basis of an output from the vibration power generation unit, wherein the control circuit executes periodic control by switching over between respective time periods for outputting power and respective time periods for not outputting power at cycles not less than twice and not more than 100 times cycles of vibration, and vibrational energy is converted into electrical energy by the periodic control.

In this case, the power generation device preferably comprises further a switch for switching over whether or not the power is outputted, and is preferably configured such that periodic control of the switch is executed so that switchover occurs between the respective time periods for outputting the power and the respective time periods for not outputting the power at the cycles not less than twice and not more than 100 times the cycles of the vibration.

Further, in this case, the periodic control is preferably a control enlarging the respective time periods for outputting the power when amplitude of the vibration is large, and enlarging the respective time periods for not outputting the power when the amplitude of the vibration is small.

The power generation device with those features preferably comprises further a circuit for measuring a period of the vibration, and control of the switch is the periodic control executed such that the respective time periods for outputting the power are equivalent to a time period M-times a period of the vibration while the respective time periods for not outputting the power are equivalent to a time period N-times the period of the vibration provided that M and N are integers not less than 0, respectively.

In this case, it is preferable that the M is 1, and the N is not less than I and not more than 100.

Further, in this case, the periodic control is preferably a control executed such that N is rendered smaller when amplitude of the vibration is large while N is rendered larger when the amplitude of the vibration is small.

The power generation device according to the invention may further comprise piezoelectric elements for converting the vibrational energy into the electrical energy, a capacitive element for converting the vibrational energy into the electrical energy, the capacitive element generating the electrical energy, due to variation in electrostatic capacity, based on the vibrational energy, or an inductor for converting the vibrational energy into the electrical energy, the inductor generating the electrical energy, due to electromagnetic induction based on the vibrational energy.

The power generation device according to the invention may further comprise a capacitor to be charged with the electrical energy generated.

The power generation device according to the invention is preferably configured such that the vibrational energy is amplified due to resonance phenomena, and the vibrational energy as amplified is converted into the electrical energy, thereby generating power.

According to another aspect of the invention, there is provided a power generation method, which is a power generation method of converting vibrational energy into electrical energy, comprising the steps of executing periodic control such that switchover occurs between respective time periods for outputting power and respective time periods for not outputting power at cycles not less than twice and not more than 100 times cycles of vibration causing generation of the vibrational energy, and generating the electrical energy by the periodic control.

In this case, the power generation method according to the invention is preferably a power generation method of switching over whether or not the power is outputted by use of a switch, and periodic control of the switch is executed such that switchover occurs between the respective time periods for outputting the power and the respective time periods for not outputting the power at the cycles not less than twice and not more than 100 times the cycles of the vibration.

Further, the step of executing the periodic control preferably comprises the sub-step of enlarging the respective time periods for outputting the power when amplitude of the vibration is large, and the sub-step of enlarging the respective time periods for not outputting the power when the amplitude of the vibration is small.

The step of executing the periodic control preferably comprises the sub-step of rendering the respective time periods for outputting the power equivalent to a time period M-times a period of the vibration, and the sub-step of rendering the respective time periods for not outputting the power equivalent to a time period N-times the period of the vibration, provided that M and N are integers not less than 0, respectively.

In such a case, it is preferable that the M is 1, and the N is not less than 1 and not more than 100.

Further, the step of executing the periodic control preferably comprises the sub-step of rendering N smaller when amplitude of the vibration is large and the sub-step of rendering N larger when the amplitude of the vibration is small.

The power generation method according to the invention may be a power generation method whereby the vibrational energy is converted into the electrical energy by use of piezoelectric elements, a power generation method whereby the vibrational energy is converted into the electrical energy by use of a capacitive element, the capacitive element generating the electrical energy, due to variation in electrostatic capacity, based on the vibrational energy, or a power generation method whereby the vibrational energy is converted into the electrical energy by use of an inductor, the inductor generating the electrical energy, due to electromagnetic induction based on the vibrational energy.

Further, the power generation method according to the invention may be a power generation method whereby a capacitor is charged with the electrical energy generated.

Still further, the power generation method according to the invention is preferably a power generation method whereby the vibrational energy is amplified by use of resonance phenomena, and the vibrational energy as amplified is converted into the electrical energy, thereby generating power.

According to the present invention, the power generation voltage can be increased even when the vibration is small in amplitude. As a result, it is possible to provide the generator generating electricity from vibration, capable of suppressing loss in a rectifying circuit and loss in a charging circuit, thereby making effective use of the power generated.

The generator with improvement in its efficiency can drive electronic equipment requiring no battery, so that it is possible to provide electronic equipment without power supply from outside, and capable of saving trouble of battery replacement.

Thus, power generation at a voltage higher than a desired voltage becomes possible and the loss in the rectifying circuit can be reduced.

### BRIEF DESCRIPTION OF THE DRAWINGS

FIG. 1 is a block diagram showing functions of one embodiment of a generator according to the invention;

FIG. 2 is a block diagram of the generator using piezoelectric elements, according to the one embodiment of the invention;

FIG. 3 is a circuit diagram including an output circuit of the generator according to the one embodiment of the invention;

FIGS. 4A and 4B are schematic representations for illustrating an advantageous effect of the invention;

FIG. 5 is another schematic representation for illustrating the advantageous effect of the invention;

FIG. 6 is a block diagram showing functions of another embodiment of a generator according to the invention;

FIG. 7 is a block diagram showing functions of still another embodiment of a generator according to the invention;

FIG. 8 is a block diagram of the generator generating power from changes in electrostatic capacity according to the still another embodiment of the invention; and

FIG. 9 is a block diagram of a vibrator of the generator taking advantage of changes in the electrostatic capacity, according to the still another embodiment of the invention.

### DETAILED DESCRIPTION OF THE PREFERRED EMBODIMENTS

Embodiments of the invention are described hereinafter with reference to the accompanying drawings.

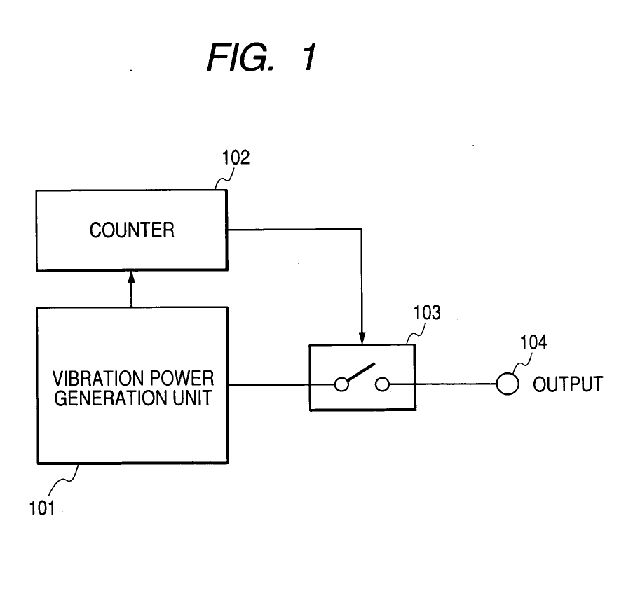

FIG. 1 is a block diagram showing functions of one embodiment of a generator according to the invention. In the figure, reference numeral 101 denotes a vibration power generation unit for converting vibrational energy into electrical energy, 102 a counter measuring cycles of vibration, and 103 a switch for controlling whether or not power of the vibration power generation unit 101 is outputted by an output of the counter 102. In the present embodiment, the cycles of the vibration is measured to thereby execute periodic control by switching over between respective time periods for outputting power and respective time periods for not outputting power.

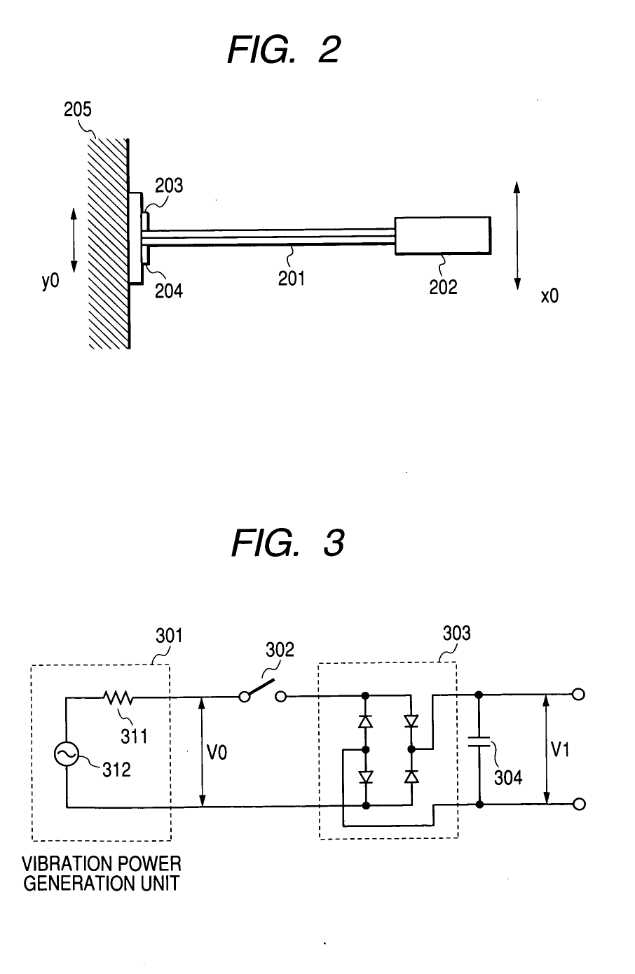

FIG. 2 shows the generator using piezoelectric elements, representing one embodiment of the vibration power generation unit 101 in FIG. 1. Reference numeral 201 denotes piezoelectric elements in the shape of a bimorph, 202 a weight, 203, 204 denote electrodes, respectively, and 205 denotes an apparatus in vibration. In the figure, there is shown a state where the piezoelectric elements are attached to the apparatus vibrating with vibration amplitude at y0, and the weight 202 is attached to the extremities of the piezoelectric elements, vibrating with vibration amplitude at x0. At this point in time, stress due to vibration acts on the piezoelectric elements 201, whereupon an AC voltage occurs across the electrodes 203, 204, due to the piezoelectric effect. In order to maximize electricity generated, it is desirable that resonance frequency, dependent on the spring constant of the piezoelectric elements 201 and the mass of the weight 202, coincides with the frequency of the apparatus 205 in vibration, which can be achieved by adjusting the shape of the piezoelectric elements 201, and the mass of the weight 202.

Further, the apparatus in vibration includes, for example, household electrical appliances, industrial machines, automobiles, and so forth. By attaching the generator generating electricity from vibration to these apparatuses, it becomes possible to operate electronic equipment located even at a place where power source wiring cannot be routed.

In the present embodiment, a case of converting vibrational energy into electrical energy with the use of the piezoelectric elements is shown by way of example; however, the embodiments of the invention are not limited to the case of using the piezoelectric elements. For a method of converting vibrational energy into electrical energy, it is also possible to employ a method of taking advantage of variation in electrostatic capacity, a method of relying on electromagnetic induction, and so forth.

FIG. 3 shows an embodiment of a circuit of the generator according to the one embodiment of the invention, for supplying power after rectification and charging of the AC voltage generated by the vibration power generation unit. Reference numeral 301 is an equivalent circuit of the vibration power generation unit, 302 a switch for controlling whether or not the power of the vibration power generation unit is outputted, 303 a rectifying circuit, and 304 a capacitor for charging the power generated. The vibration power generation unit can be expressed by an AC voltage power supply 312, and a power supply internal resistance 311, representing an equivalent circuit corresponding to a power generation part as seen from, for example, the electrodes 203, 204, in FIG. 2. The switch 302 can be implemented by, for example, a MOS transistor, and can execute switching at high speed by use of the MOS transistor. Further, the rectifying circuit 303 can be made up by use of PN diodes, Schottky diodes, or MOS transistors.

Since a voltage V0 generated by generation of electricity is unable to pass through the rectifying circuit 303 unless the voltage V0 is higher than a voltage V1 across both ends of the capacitor 304, the voltage V0 otherwise cannot be taken out as power. In practice, because of a voltage loss in the rectifying circuit 303, the voltage V0 generated by the generation of electricity has to be greater than a value of the voltage V1 across the both ends of the capacitor 304, added with the voltage loss in the rectifying circuit 303. In the case where the rectifying circuit 303 is made up of silicon diodes, because the voltage loss thereof generally corresponds to voltage loss for two diodes, the voltage loss will be at a value in a range of about 1.4 to 1.6 V. When the voltage V0 is low, there will be an increase in the voltage loss in the rectifying circuit 303, and assuming that, for example, the voltage V0 is at 2.0 V and the voltage loss in the rectifying circuit 303 is 1.6 V, the voltage V1 will be at 0.4 V, so that the voltage loss represents as much as 80%.

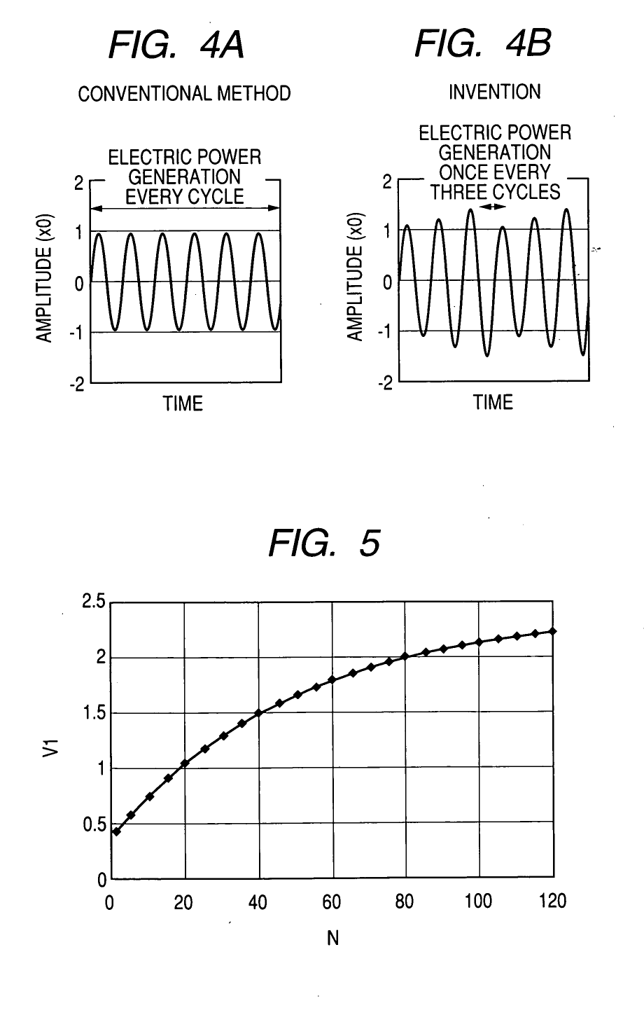

FIGS. 4A and 4B are schematic representations for illustrating an advantageous effect of the invention, showing amplitudes of a vibrator with the passage of time. FIG. 4A shows the case of a conventional method, and FIG. 4B the case of a method according to the invention. Having taking note of the fact that with a method of generating electricity for every cycle of vibration, which is the conventional method of generating electricity from vibration, the amplitude x0, during generation of electricity by, for example, the piezoelectric elements shown in FIG. 2, becomes smaller than amplitude when no electricity is generated, the inventor et al. have found out that there occurs an increase in amplitude when power is taken out by providing time periods when no power is taken out as shown in FIG. 4B. Due to this, a power generation voltage becomes higher, thereby enabling efficiency of power supply to be enhanced. It is evident from an example shown in FIG. 4B that by generating power only once every three cycles, there occurs an increase in amplitude in respective time periods when power is not taken out.

FIG. 5 shows an output voltage V1 in the case where power is generated only once every N cycles. In this figure, there is shown variation in the output voltage V1 on-a condition that in the case of the conventional method, the voltage V0 is at 2.0 V and the voltage loss in the rectifying circuit is 1.6 V. If N is excessively large in value, saturation occurs, however, it is evident that the output voltage is controllable in a wide range. It has been found out from studies conducted by the inventor, et al. that the upper limit of N is desirably a value not more than one third of Q-value in resonance of vibration. Accordingly, assuming that Q-value is a value on the order of 100, N up to on the order of 30 can be adopted. That is, the output voltage V1 that is used to be at 0.4 V according to the conventional technology can be increased up to about 1.3 V according to the invention. It can be said from this that efficiency of electricity generation can be enhanced not less than three times over that in the past if the loss in the rectifying circuit is taken into account.

There are worries that as respective time periods for taking out power are shortened, power obtained will decrease, however, the inventor et al. have found out that the power obtained will not decrease in practice even if the respective time periods for taking out power are shortened. This is described in detail hereinafter. Herein, power generated by generation of electricity is calculated. That is, the loss in the rectifying circuit is not included. First, assuming that amplitude of external vibration is y0, and amplitude of resonance is y0, power in the case of taking out energy all the time is found by the following expression:

$$power = \frac{1}{2} k ( {( x0 + ny0 )}^{2} - {x0}^{2} f = \frac{1}{2} k ( 2 x0y0 + {y0}^{2} ) f \qquad ( 1 )$$

where k=spring constant of vibration, and f=frequency of vibration. In this case, a model is assumed where energy corresponding to y0 can be taken out for every cycle in a system vibrating with amplitude at x0 in a state of equilibrium.

Meanwhile, power in the case of generating power only once for every n cycles is found by the following expression:

$$power = \frac{1}{2} k \frac{1}{n} ( {( x0 + ny0 )}^{2} - {x0}^{2} ) f = \frac{1}{2} k ( 2 x0y0 + {ny0}^{2} ) f \qquad ( 2 )$$

Included herein is an effect that power is reduced to one n-th because the power is generated only once for every n cycles. Further, a condition is assumed that amplitude immediately after the generation of the power reverts to the amplitude at x0 in the state of equilibrium. Although an assumption is made on a model where amplitude linearly increases in respective time periods when the power is not taken out, an error is tolerable provided that n is a value corresponding to up to about one third of Q-value of vibration. On the basis of the expression (2), the greater the n value, the larger the power becomes, however, in practice, this will not occur because an increase in amplitude during the respective time periods when the power is not taken out will reach saturation.

A ratio between the two expressions as described above is found by the following expression:

$$\frac{1}{2} k ( 2 x0y0 + {ny0}^{2} ) f / \frac{1}{2} k ( 2 x0y0 + {y0}^{2} ) f = \frac{2 x0 + ny0}{2 x0 + y0} \qquad ( 3 )$$

A ratio of x0 to y0 is dependent on Q-value, and x0 is normally not less than several-ten times as large as y0. It can be said in conclusion that if n is the value corresponding to up to about one third of Q-value of vibration, there is no change in the power generated. As for cycles at which switchover is executed between respective time periods for generating the power, and the respective time periods for not generating the power, switchover is preferably executed at cycles not more than 100 times cycles of the vibration.

It can be said from results described that with the invention, the voltage can be changed without changing the power generated, and the efficiency of electricity generation as a whole can be enhanced by reducing the loss in the rectifying circuit.

Control according to the invention may be changed depending on magnitude of the amplitude of vibration. For example, in the case of the control for generating power, only once every N cycles, N is rendered smaller when the amplitude of the vibration is large while N is rendered larger when the amplitude of the vibration is small. In other words, the control is executed so as to increase the voltage when the amplitude is small. With the conventional method, once the capacitor is charged at a large amplitude, the capacitor cannot be charged at a small amplitude because the voltage is low, so that a problem has arisen that it is impossible to efficiently utilize the vibrational energy. In contrast, with the method according to the invention, the voltage can be increased even when the amplitude is small, so that it is possible to efficiently utilize the vibrational energy.

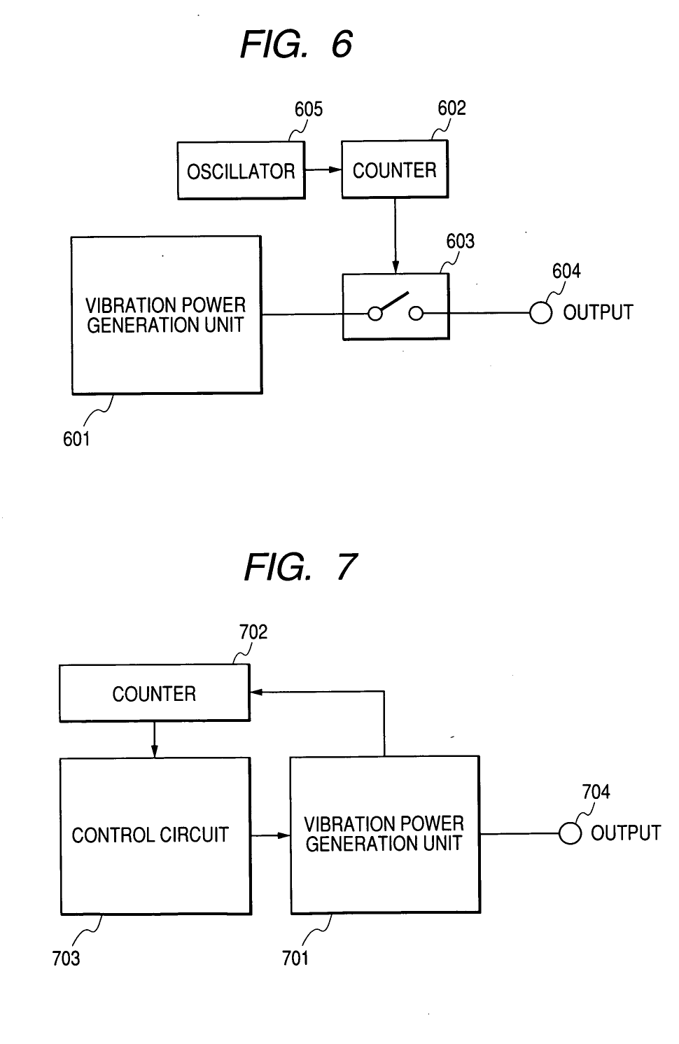

FIG. 6 is a block diagram showing functions of another embodiment of a generator according to the invention. In the figure, reference numeral 601 denotes a vibration power generation unit for converting vibrational energy into electrical energy, 605 an oscillator independent from the vibration power generation unit 601, 602 a counter for measuring cycles of the oscillator 605, and 603 a switch for controlling whether or not power of the vibration power generation unit 601 is outputted. With the present embodiment, cycles of oscillation, independent from cycles of vibration, are measured to thereby execute periodic control by switching over between respective time periods for outputting power and respective time periods for not outputting power.

In carrying out the invention, control on whether or not the power of electricity generated from vibration is outputted need not exactly be in sync with the cycles of the vibration in this case, so that the control can be executed with the oscillator that is independent from the vibration power generation unit 601 as with the case of the present embodiment. By so doing, since it is unnecessary to measure the cycles of the vibration power generation unit that undergoes variation in amplitude, the control can be implemented with ease.

A mechanism for converting vibrational energy into electrical energy according to the present embodiment as well can be applied to the respective cases of using the piezoelectric elements, variation in electrostatic capacity, and electromagnetic induction.

FIG. 7 is a block diagram showing functions of still another embodiment of a generator according to the invention. In the figure, reference numeral 701 denotes a vibration power generation unit for converting vibrational energy into electrical energy, 702 a counter measuring cycles of vibration, and 703 a control circuit for executing control on whether or not power of the vibration power generation unit 701 is outputted. With the present embodiment, there is adopted a method whereby the output of the vibration power generation unit 701 is switched over between output ON/OFF without a switch provided separately.

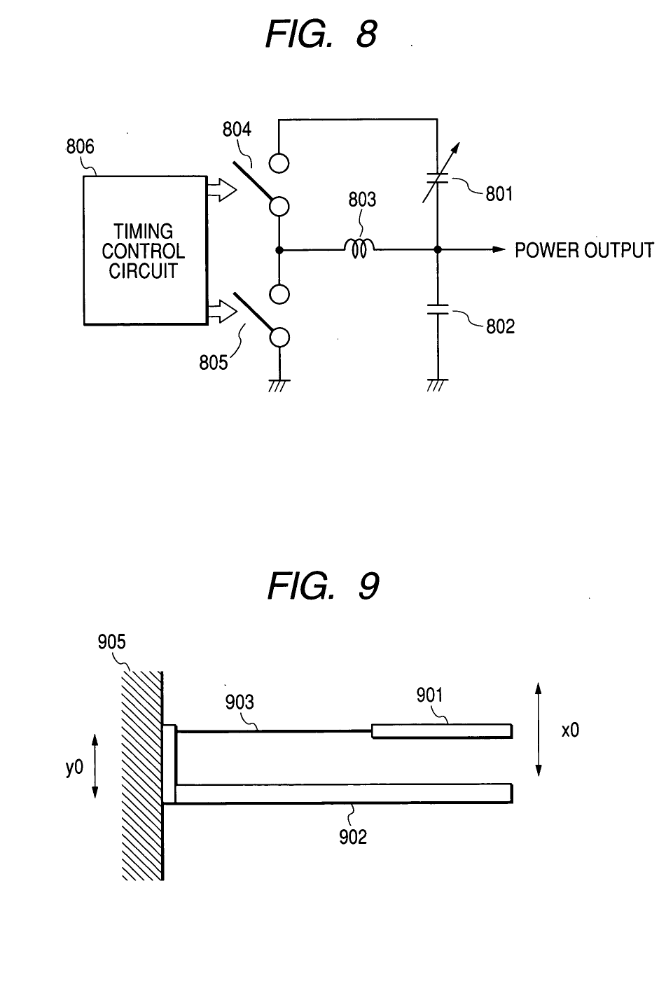

FIG. 8 shows an embodiment of the vibration power generation unit 701 in FIG. 7, for carrying out a control method. In the figure, reference numeral 801 denotes a variable capacitor undergoing periodic changes in electrostatic capacity value, due to vibration, 802 a capacitor for storing electric charge, 803 an inductor for producing electromotive force from change in current, and 804, 805 denote switches, respectively. These switches each can be made up of, for example, a MOS transistor. Reference numeral 806 denotes a timing control circuit for controlling the switches. In the present embodiment, there is adopted a power generation method whereby change in electrostatic capacity is caused to occur by vibration, and electricity is generated from the change in the electrostatic capacity.

Now, the workings of electricity generation are described hereinafter. The timing control circuit 806 executes control on charging and discharging of electric charge of the variable capacitor 801 that undergoes periodic changes in the electrostatic capacity value, due to vibration, and power is generated by obtaining energy of electric charge transfer in space with a field potential. More specifically, when a capacitance value of the variable capacitor 801 is at the maximum, the switch 805 is caused to be in a conducting state for an instant to be immediately turned into a non-conducting state while the switch 804 is caused to be in a conducting state for an instant to be immediately turned into a non-conducting state. By so doing, the electric charge of the capacitor 802 is charged into the variable capacitor 801. Meanwhile, when the capacitance value of the variable capacitor 801 is at the minimum, the switch 804 is caused to be in a conducting state for an instant to be immediately turned into a non-conducting state while the switch 805 is caused to be in a conducting state for an instant to be immediately turned into a non-conducting state. By so doing, the electric charge of the variable capacitor 801 is charged into the capacitor 802. By repeating such controls, the vibrational energy can be converted into the electrical energy.

This method can be implemented by stopping controls of switches 1, and 2, in respective time periods for not generating power. That is, by executing ON/OFF controls of the switches 1, and 2, in respective time periods for generating power, and by stopping the controls of the switches 1, and 2, in the respective time periods for not generating power, an output voltage can be controlled by the method according to the invention. With the present embodiment, since it is unnecessary to add another switch separately for output from the generator, the control can be executed without causing deterioration in efficiency of the generator.

FIG. 9 shows an embodiment of the generator using the variable capacitor 801 in FIG. 8, undergoing periodic changes in electrostatic capacity value, due to vibration, as a vibrator. In the figure, reference numeral 901 denotes a weight doubling as an electrode, 902 an opposition electrode against the weight 901, 903 a flat spring, and 905 an apparatus in vibration. Vibration of the apparatus 905 vibrating with amplitude at y0 provide the weight 901 with vibration with amplitude at x0 due to resonance dependent on the spring constant of the flat spring 903 and the mass of the weight 901. At this point in time, electrostatic capacity is developed between the electrodes 901 and 902, thereby implementing the variable capacitor that undergoes periodic changes in electrostatic capacity value.

Several embodiments of the invention have been described as above, however, it is to be pointed out that the invention is not limited thereto, and the invention provides the method of generating electricity from vibration, whereby efficiency in generation of electricity is enhanced by executing the periodic control on respective time periods for generating power as well as respective time periods for not generating power.

1. A power generation device comprising:
a vibration power generation unit;
a control circuit for controlling the vibration power generation unit; and
a counter for feeding the control circuit with a clock on the basis of an output from the vibration power generation unit,
wherein the control circuit executes periodic control by switching over between respective time periods for outputting power and respective time periods for not outputting power at cycles not less than twice and not more than 100 times cycles of vibration, and vibrational energy is converted into electrical energy by the periodic control.

2. A power generation device according to claim 1, further comprising:
a switch for switching over whether or not the power is outputted,
wherein periodic control of the switch is executed such that switchover occurs between the respective time periods for outputting the power and the respective time periods for not outputting the power at the cycles not less than twice and not more than 100 times the cycles of the vibration.

3. A power generation device according to claim 2, wherein the periodic control is a control enlarging the respective time periods for outputting the power when amplitude of the vibration is large, and enlarging the respective time periods for not outputting the power when the amplitude of the vibration is small.

4. A power generation device according to claim 2, further comprising a circuit for measuring a period of the vibration,
wherein control of the switch is the periodic control executed such that the respective time periods for outputting the power are equivalent to a time period M-times a period of the vibration while the respective time periods for not outputting the power are equivalent to a time period N-times the period of the vibration provided that M and N are integers not less than 0, respectively.

5. A power generation device according to claim 4, wherein the M is 1, and the N is not less than 1 and not more than 100.

6. A power generation device according to claim 4, wherein the periodic control is a control executed such that N is rendered smaller when amplitude of the vibration is large while N is rendered larger when the amplitude of the vibration is small.

7. A power generation device according to claim 1, further comprising piezoelectric elements for converting the vibrational energy into the electrical energy.

8. A power generation device according to claim 1, further comprising a capacitive element for converting the vibrational energy into the electrical energy,
wherein the capacitive element generates the electrical energy, due to variation in electrostatic capacity, based on the vibrational energy.

9. A power generation device according to claim 1, further comprising an inductor for converting the vibrational energy into the electrical energy,
wherein the inductor generates the electrical energy, due to electromagnetic induction based on the vibrational energy.

10. A power generation device according to claim 1, further comprising a capacitor to be charged with the electrical energy generated.

11. A power generation device according to claim 1, wherein the vibrational energy is amplified due to resonance phenomena, and the vibrational energy as amplified is converted into the electrical energy, thereby generating power.

12. A power generation method, said method being a power generation method of converting vibrational energy into electrical energy, comprising the steps of:
executing periodic control such that switchover occurs between respective time periods for outputting power and respective time periods for not outputting power at cycles not less than twice and not more than 100 times cycles of vibration causing generation of the vibrational energy; and
generating the electrical energy by the periodic control.

13. A power generation method according to claim 12, said method being a power generation method of switching over whether or not the power is outputted by use of a switch,
wherein periodic control of the switch is executed such that switchover occurs between the respective time periods for outputting the power and the respective time periods for not outputting the power at the cycles not less than twice and not more than 100 times the cycles of the vibration.

14. A power generation method according to claim 13, wherein the step of executing the periodic control comprises the sub-step of enlarging the respective time periods for outputting the power when amplitude of the vibration is large, and the sub-step of enlarging the respective time periods for not outputting the power when the amplitude of the vibration is small.

15. A power generation method according to claim 13, wherein the step of executing the periodic control comprises the sub-step of rendering the respective time periods for outputting the power equivalent to a time period M-times a period of the vibration, and the sub-step of rendering the respective time periods for not outputting the power equivalent to a time period N-times the period of the vibration, provided that M and N are integers not less than 0, respectively.

16. A power generation method according to claim 15, wherein the M is 1, and the N is not less than 1 and not more than 100.

17. A power generation method according to claim 15, wherein the step of executing the periodic control comprises the sub-step of rendering N smaller when amplitude of the vibration is large and the sub-step of rendering N larger when the amplitude of the vibration is small.

18. A power generation method according to claim 12, wherein the vibrational energy is converted into the electrical energy by use of piezoelectric elements.

19. A power generation method according to claim 12, said method being a power generation method of converting the vibrational energy into the electrical energy by use of a capacitive element,
wherein the capacitive element generates the electrical energy, due to variation in electrostatic capacity, based on the vibrational energy.

20. A power generation method according to claim 12, said method being a power generation method of converting the vibrational energy into the electrical energy by use of an inductor,
wherein the inductor generates the electrical energy, due to electromagnetic induction based on the vibrational energy.

21. A power generation method according to claim 12, wherein a capacitor is charged with the electrical energy generated.

22. A power generation method according to claim 12, wherein the vibrational energy is amplified by use of resonance phenomena, and the vibrational energy as amplified is converted into the electrical energy, thereby generating power.
